(19) United States
(12) Patent Application Publication
(10) Pub. No.: US 2011/0089467 A1
(43) Pub. Date: Apr. 21, 2011

(54) OHMIC CONTACT OF III-V SEMICONDUCTOR DEVICE AND METHOD OF FORMING THE SAME

(75) Inventors: Edward Yi CHANG, HSINCHU (TW); Chien-I KUO, Hsinchu City (TW); Chun-Yen CHANG, HSINCHU (TW)

(73) Assignee: NATIONAL CHIAO TUNG UNIVERSITY, HSINCHU (TW)

(21) Appl. No.: 12/693,444

(22) Filed: Jan. 26, 2010

(30) Foreign Application Priority Data
Oct. 21, 2009 (TW) 98135626

(51) Int. Cl. H01L 29/778; H01L 21/335

(52) U.S. Cl. 257/194; 438/172; 257/E29.246; 257/E21.403

(57) ABSTRACT

Heavily doped epitaxial SiGe material or epitaxial InₓGa₁₋ₓAs are used to form the source and drain of III-V semiconductor device to apply stress to the channel of III-V semiconductor device. Therefore, the electron mobility can be increased.

### CROSS-REFERENCE TO RELATED APPLICATION

This application claims the priority benefit of Taiwan application serial no. 98135626, filed Oct. 21, 2009, the full disclosure of which is incorporated herein by reference.

### BACKGROUND

1. Technical Field

The disclosure relates to a semiconductor device and a method of forming the same. More particularly, the disclosure relates to a III-V semiconductor device and a method of forming the same

2. Description of Related Art

The development of the high frequency wireless communication is very fast, and the band of the sub-millimeter wave is gradually used as the communication band of military and home security or applied on monolithic microwave integrated circuit (MMIC) of the next generation's imaging system. These applications require that the transistor possesses the properties of high gain and low noise in high-frequency operation. Reducing the gate length and increasing the electron mobility are the methods to increase the transistor's operation frequency.

Moreover, the Moor's law is always followed to increase the transistor's number on unit area in the semiconductor technical field. That is, the sizes of the semiconductor devices are decreased to half of the original size for every 18 months. However, the ultimate size of complementary metal-oxide-semiconductor (CMOS) transistor will be finally reached. For example, 10 nm is the ultimate size of the gate length. At that time, the size of semiconductor devices cannot be reduced anymore.

Since high performance is required for the semiconductor integrated circuit, the N-channel devices are mainly replaced by III-V semiconductor devices, and the P-channel devices are mainly replaced by Ge semiconductor device. Therefore, in the semiconductor process smaller than 22 nm, how to integrate silicon, III-V, and Ge semiconductor devices is a hot research topic.

Among the semiconductor devices above, since the electron mobility of high electron mobility transistors (HEMTs) of III-V semiconductor devices is high, is HEMTs are very suitable to be used in high-frequency and high-speed logic operation. However, conventional source and drain of HEMTs are formed by depositing multi-layered noble metals, such as Au, Pt and Ge, on a semiconductor substrate and then high-temperature annealing to decrease the contact resistance between the noble metals and the semiconductor substrate. Therefore, the P-channel devices are often contaminated by the noble metals to produce electrical problems. For example, if the noble metal has high electrical conductivity, it is often that the contaminated P-channel devices cannot be normally turned on and off.

### SUMMARY

Accordingly, a III-V semiconductor device and a method forming the same are provided.

According to an embodiment, a metal-semiconductor field effect transistor (MESFET) comprises a channel layer and a gate sequentially on a substrate. A source and a drain are on two sides of the channel layer and directly contact the channel layer. The channel layer is made of III-V semiconductor. The source and the drain are made of a heavily-doped semiconductor such as heavily-doped epitaxial SiGe or epitaxial InGaAs.

The method of forming the source and drain comprises forming a hard mask layer on the channel layer. Then, the hard mask layer, the channel layer and the substrate are patterned to form two trenches in the channel layer and the substrate. Next, a heavily-doped epitaxial semiconductor layer is formed in is the trenches and on the hard mask layer. Finally, the hard mask layer and the epitaxial semiconductor layer on the hard mask layer are removed to leave the epitaxial semiconductor layers in the trenches to be used as a source and a drain of the MESFET.

According to another embodiment, a high electron mobility transistor (HEMT) is provided. The HEMT comprises a channel layer, a Schottky layer, a cap layer and a gate sequentially on a substrate. A source and a drain are on two sides of the channel layer, the Schottky layer, and the cap layer and directly contact the channel layer, the Schottky layer, and the cap layer. The channel layer is made of III-V semiconductor. The source and the drain are made of a heavily-doped semiconductor such as heavily-doped epitaxial SiGe or epitaxial InGaAs.

The method of forming the source and drain comprises forming a hard mask layer on the cap layer. Then, the hard mask layer, the cap layer, the Schottky layer, the cannel layer, and the substrate are patterned to form two trenches in the cap layer, the Schottky layer, the cannel layer, and the substrate. Next, a heavily-doped epitaxial semiconductor layer is formed in the trenches and on the hard mask layer. Finally, the hard mask layer and the epitaxial semiconductor layer on the hard mask layer are removed to leave the epitaxial semiconductor layers in the trenches to be used as a source and a drain of the HEMT.

In light of above, heavily-doped epitaxial semiconductor replaces the noble metals to be the source and drain of the III-V semiconductor devices. The cost is saved, and the contaminant problem of P-channel devices is solved. Moreover, the electron mobility in the channel can be further increased by the heavily-doped epitaxial semiconductor.

It is to be understood that both the foregoing general description and the following detailed description are by examples, and are intended to provide further explanation of the invention as claimed.

### BRIEF DESCRIPTION OF THE DRAWINGS

FIG. 1 is a cross-sectional diagram of a HEMT according to an embodiment of this invention.

FIGS. 2A-2B are I-V modeling results of the HEMT in FIG. 1 and a conventional HEMT, respectively.

FIGS. 3A-3D are cross-sectional diagrams of a process for forming the HEMT in FIG. 1.

FIG. 4 is a cross-sectional diagram of a MESFET according to another embodiment of this invention.

FIGS. 5A-5C are cross-sectional diagrams of a process for forming the MESFET in FIG. 4.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. According to an embodiment, the noble metals are replaced by heavily-doped epitaxial semiconductor, such as Ge, SiGe, or InGaAs, to be the material of the source and drain of the III-V semiconductor device. Since the lattice constants, i.e. the lattice sizes, are different, stress is often produced between the contact interface between the epitaxial semiconductor and the III-V semiconductor. Hence, the phenomenon can be used to increase the electron mobility in the channel of the III-V semiconductor device.

In the table below, lattice constant of the commonly used III-V semiconductor and the IVA semiconductor are listed. It can be known that if the III-V semiconductor is composed by the Ga and As in the fourth period, the lattice constant is often greater than the lattice constant of Si in the third period and Si-doped Ge in the fourth period. If the GaAs is further doped by the Indium in the fifth period, the lattice constant is further increased.

| III-V | Lattice Constant (Å) | IV | Lattice Constant (Å) |
|---|---|---|---|
| GaAs | 5.65 | Si | 5.43 |
| In_{0.53}Ga_{0.47}As | 5.83 | Ge | 5.65 |

If the stress between the semiconductors with different lattice constants is too small, the electron mobility cannot be effectively increased. If the stress between the semiconductors with different lattice constants is too large, too many defects can occur in the interface to cause poor electrical property. Therefore, according to an embodiment, the lattice constant difference is about 0.5%−3.5%. According to another embodiment, the lattice constant difference is about 0.5%−3%. According to yet another embodiment, the lattice constant difference is about 0.5%−1%. Hence, the stress occurred in the interface between the semiconductors with different lattice constants can be controlled in the desired range.

In the table below, some pairs of semiconductors with different lattice constants are listed. From the table, it can be known that the composition of the second semiconductor can be adjusted according to the composition of the first semiconductor. Therefore, the interface stress can be in a proper range.

| | x range of InₓGa₁₋ₓAs, | Lattice constant |
|---|---|---|
| The first semiconductor | the second semiconductor | difference (%) |
| Si_{0.05}Ge_{0.95} | 0.20-0.53 | 0.5-3.5 |
| Ge | 0.20-0.60 | 0.5-3.5 |
| In_{0.4}Ga_{0.6}As | 0.5-0.55 | 0.5-1 |

HEMT and MESFET are used as examples to explain how to use epitaxial SiGe or epitaxial InGaAs can be used as the material of the source and drain to produce new semiconductor devices.

### High Electron Mobility Transistor (HEMT)

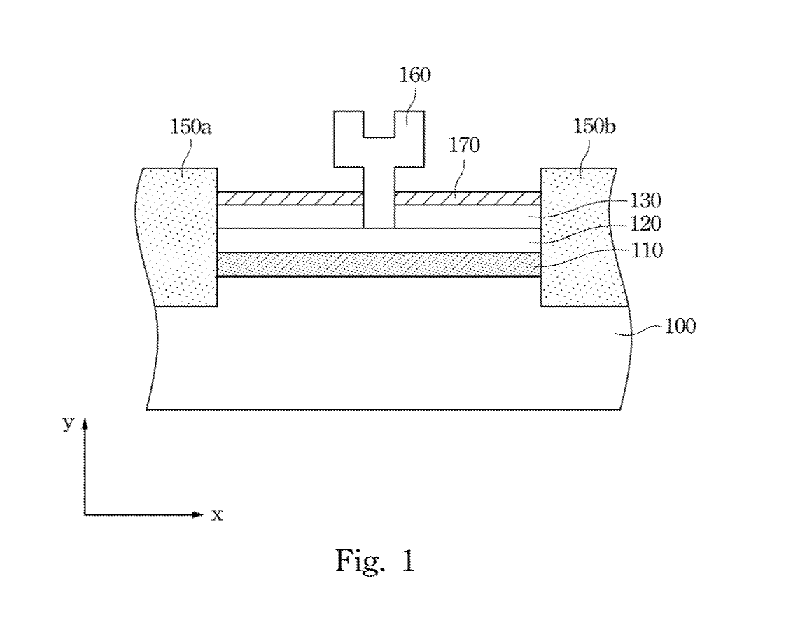

FIG. 1 is a cross-sectional diagram of a HEMT according to an embodiment of this invention.

In FIG. 1, a channel layer 110, a Schottky layer 120, a cap layer 130, and a passivation layer 170 are sequentially located on a substrate 100. A source 150a and a drain 150b are located deep into the two sides of the substrate 100, the channel layer 110, and the Schottky layer 120. A gate 160 is located on the center above the Schottky layer 120.

The material of the substrate 100 can be GaAs, InP, or Si, for example. The material of the channel layer 110 can be InGaAs or InAs, for example. The material of the Schottky layer 120 can be InAlAs, for example. The material of the cap layer 130 can be heavily-doped InGaAs, for example. The material of the passivation layer 170 can be silicon nitride, for example. The material of the source 150a and the drain 150b can be heavily doped epitaxial SiGe or epitaxial GaAs, for example. The material of gate 160 can be Ti/Pt/Au or Pt/Ti/Pt/Au, for example.

According to the materials above, the lattice constant of the source 150a and drain 150b are smaller than the lattice constant of the substrate 100, the channel layer 110, and the Schottky layer 120. In addition, the source 150a and drain 150b in FIG. 1 are deep into the two sides of the substrate 100, the channel layer 110, and the Schottky layer 120. Therefore, the source 150a and drain 150b can apply tensile stress to the substrate 100, the channel layer 110, and the Schottky layer 120 on the horizontal x direction and apply compressed stress to the substrate 100, the channel layer 110, and the Schottky layer 120 on the vertical y direction. Since the channel layer 110 constituting the electron's moving path is parallel to x direction, the electron mobility can be increased to increase the device current.

The I-V (current-voltage) curves were compared by computer modeling the HEMT of FIG. 1 and a conventional HEMT. The HEMT structure of FIG. 1 sequentially has 2 inch semi-insulating InP substrate 100, 500 nm of In_{0.52}Al_{0.48}As buffer layer, 10 nm of In_{0.53}Ga_{0.47}As channel layer 110, 4 nm of In_{0.52}Al_{0.48}As space layer, 10 nm of In_{0.52}Al_{0.48}As Schottky layer 120, 4 nm of InP etch stop layer, and 35 nm of In_{0.53}Ga_{0.47}As cap layer 130. The Si δ-doping concentration of the Schottky layer 120 was 4×10¹² cm⁻². The doping concentration of the cap layer 130 was 2×10¹⁹ cm⁻². The material of the source 150a and the drain 150b is In_{0.4}Ga_{0.6}As doped with Si at a concentration of 4×10¹⁹ cm⁻³.

The conventional HEMT's structure is similar to the HEMT's structure above. The only difference is that the source and drain are located on the cap layer 130 in FIG. 1 and not deep into the Schottky layer 120, the channel layer 110 and the substrate. The material of the source and drain is an alloy that is formed by annealing Au/Ge/Ni/Au metal layers.

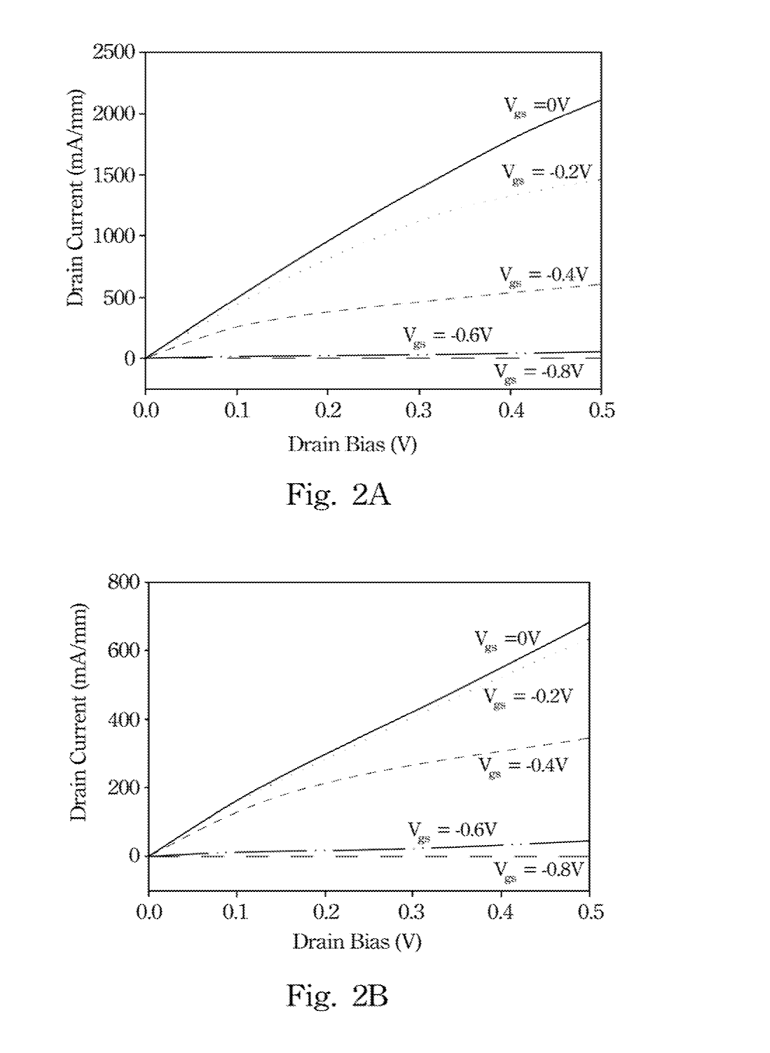

The computer modeling uses SILVACO TCAD package software. The modeling results are shown in FIGS. 2A-2B. FIGS. 2A-2B are I-V modeling results of the HEMT in FIG. 1 and a conventional HEMT, respectively. From FIGS. 2A-2B, it can be know that when drain voltage is 0.5 V, the drain current of the HEMT in FIG. 1 is about 2100 mA/mm, but the drain current of the conventional HEMT is only 650 mA/mm. That is, under the same drain voltage, the drain current of the HEMT of FIG. 1 is about 3 times of the drain current of the conventional HEMT.

Moreover, since the source 150a and the drain 150b are made of heavily-doped epitaxial SiGe or epitaxial InGaAs, the parasitic capacitor of gate/source and gate/drain can be further reduced. Furthermore, the parasitic resistance of source to gate can be reduced, too.

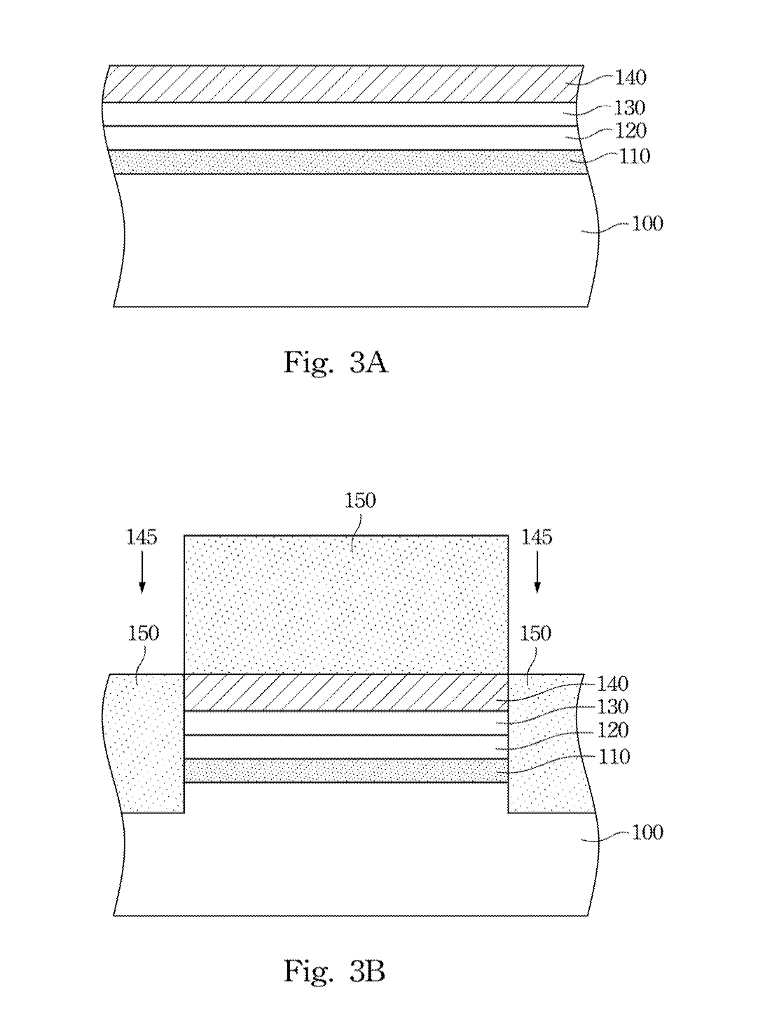

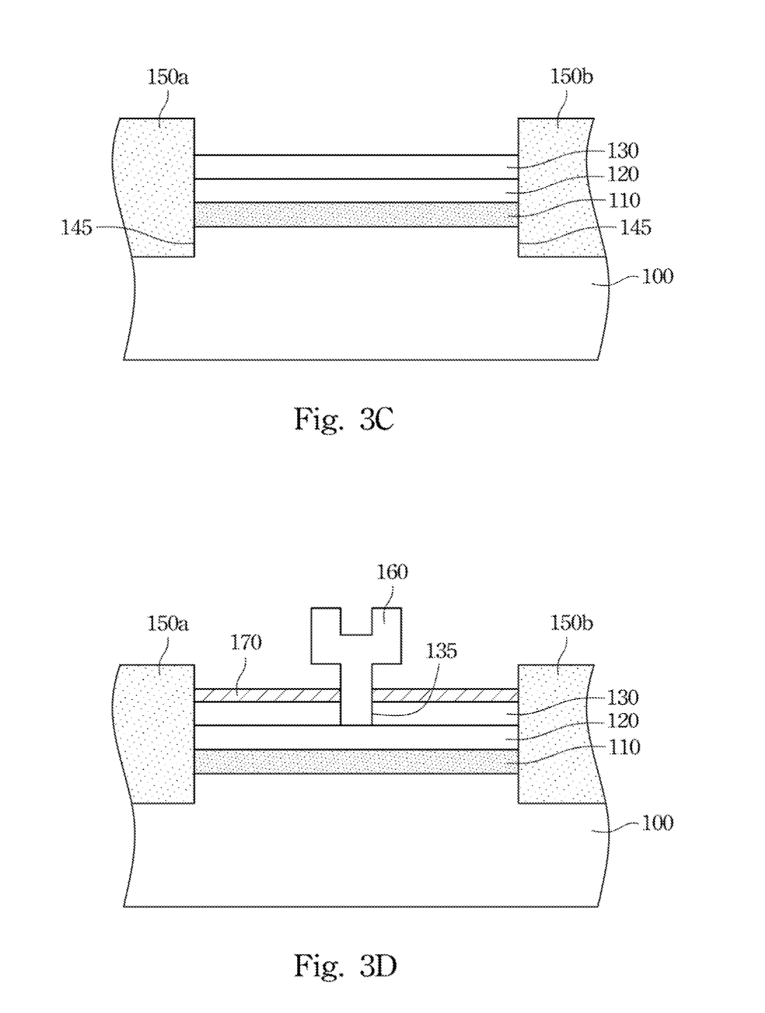

FIGS. 3A-3D are cross-sectional diagrams of a process for forming the HEMT in FIG. 1. In FIG. 3A, the channel layer 110, the Schottky layer 120, the cap layer 130 and a hard mask layer 140 are sequentially formed on the substrate. The material of the substrate 100, the channel layer 110, the Schottky layer 120, and the cap layer 130 are as described above. The material of the hard mask layer 140 can be silicon oxide, for example.

In FIG. 3B, the hard mask layer 140, the Schottky layer 130, the channel layer 120, and the substrate 100 are patterned to form trenches 145 therein. Next, an epitaxial semiconductor layer 150 is formed on the hard mask layer 140 and in the trenches 145. The material of the epitaxial semiconductor layer 150 is the same as the material of the source 150a and the drain 150b. The method of the pattering above can be photolithography and etching.

In FIG. 3C, the hard mask layer 140 and the epitaxial semiconductor layer 150 thereon can be removed by wet etching to leave the source 150a and the drain 150b in the trenches 145. The wet etching above can use an etchant solution containing fluoride anion, such as HF solution.

In FIG. 3D, the cap layer 130 is patterned to form a gate opening 135 between the source 150a and the drain 150b. Then, the gate 160 is formed in the gate opening 135. Finally, a passivation layer 170 is formed on the exposed cap layer 130. The methods of patterning the cap layer 130, and forming the gate 160 and the passivation layer 170 can be any suitable methods. Since many conventional methods are available for the methods of patterning the cap layer 130, and forming the gate 160 and the passivation layer 170, the detailed descriptions of these methods above are omitted here.

### Metal Semiconductor Field Effect Transistor (MESFET)

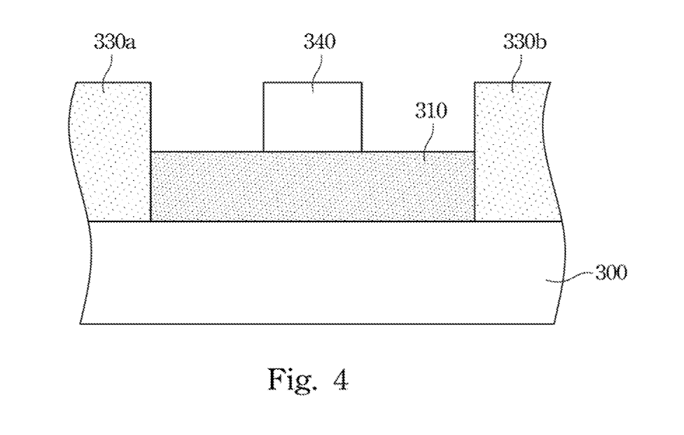

FIG. 4 is a cross-sectional diagram of a MESFET according to another embodiment of this invention. In FIG. 4, a channel layer 310 and a gate 340 are sequentially located on the substrate 300. A source 330a and a drain 330b are located on the two sides of the channel layer 310. The material of the substrate 300 can be GaAs, In P, or Si, for example. The material of the channel layer 310 can be GaAs, InGaAs, or InAs, for example. The material of the gate 340 can be Ti/Pt/Au or Pt/Ti/Pt/Au, for example. The material of the source 330a and the drain 330b can be heavily doped epitaxial SiGe or epitaxial InGaAs, for example.

Since the source 330a and the drain 330b are located on the two sides of the channel 310, and the lattice constant of the source 330a and the drain 330b are smaller than the lattice constant of the channel 310, a tensile stress is applied on the channel 310. Therefore, the electron mobility in the channel layer 310 can be increased by the source 330a and the drain 330b made of the epitaxial SiGe or the epitaxial InGaAs to increase the device current.

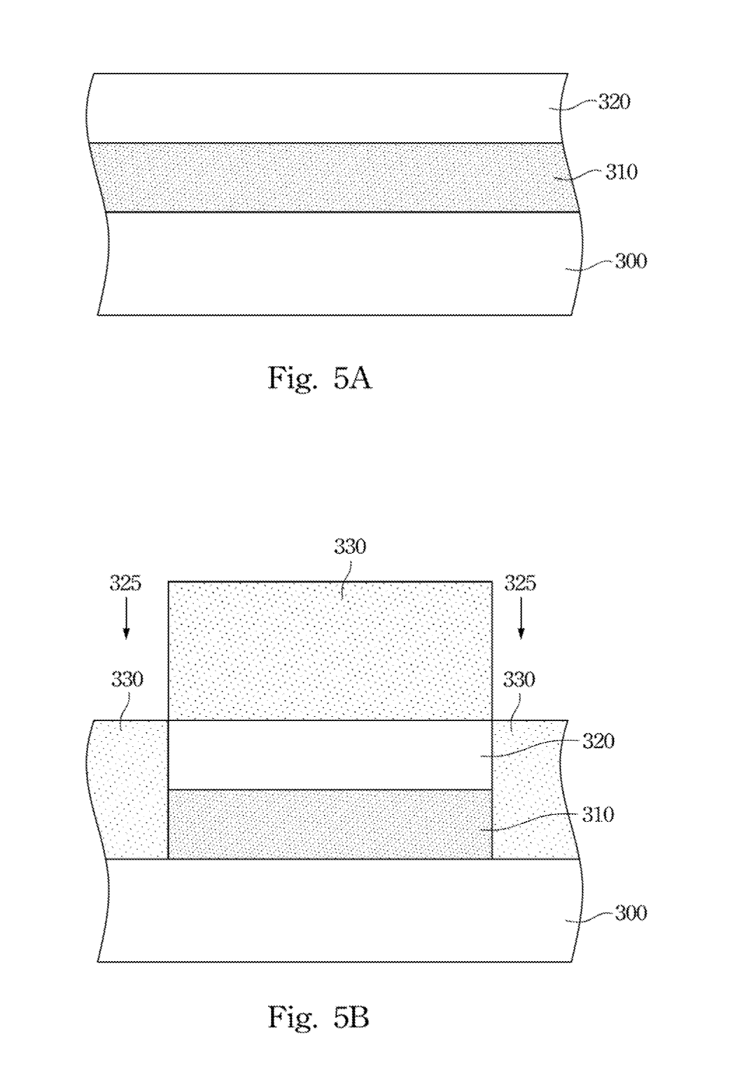

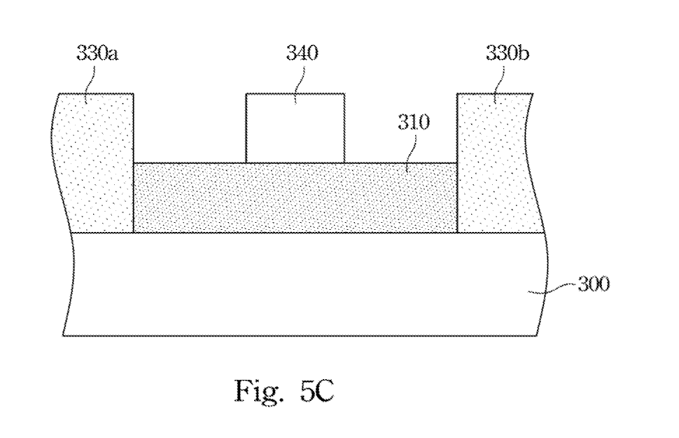

FIGS. 5A-5C are cross-sectional diagrams of a process for forming the MESFET in FIG. 4. In FIG. 5A, the channel layer 310 and a hard mask layer 320 are sequentially formed on the substrate 300. The material of the substrate 300 and the channel layer 310 are as described above. The material of the hard mask layer 320 can be silicon oxide, for example.

In FIG. 5B, the hard mask layer 320 and the substrate 300 are patterned to form trenches 325 therein. Next, an epitaxial semiconductor layer 330 is formed on the hard mask layer 320 and in the trenches 325. The material of the epitaxial semiconductor layer 320 is the same as the material of the source 330a and the drain 330b above. The method of the pattering above can be photolithography and etching.

In FIG. 5C, the hard mask layer 320 and the epitaxial semiconductor layer 330 thereon can be removed by wet etching to leave the source 330a and the drain 330b in the trenches 325. The wet etching above can use an etchant solution containing fluoride anion, such as HF solution. Next, the gate 340 is formed on the channel layer 310 by any suitable methods. Since many conventional methods are available for the methods of forming the gate 340, the detailed description of the method of forming the gate 340 is omitted here.

Accordingly, the production cost can be saved and the contamination problem of the P channel devices can be solved by using heavily-doped epitaxial SiGe or InGaAs to replace the conventional noble metals to form the source and drain of a III-V semiconductor device. Moreover, the electron mobility of the III-V semiconductor devices can be increased by using heavily-doped epitaxial SiGe or InGaAs as the source and drain to increase the DC and microwave performance of the III-V semiconductor devices. This make the III-V semiconductor devices can be more suitably used in applications requiring high-speed and low-power consumption, such as microwave communication devices or digital logic devices.

The reader's attention is directed to all papers and documents which are filed concurrently with his specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A III-V semiconductor device, comprising:
a substrate;
a channel layer on the substrate, wherein the channel layer is made of a III-V semiconductor;
a gate on the channel layer; and
a source and a drain on two sides of the channel layer and directly contacting the channel layer, wherein the source and the drain are made of heavily-doped epitaxial SiGe or epitaxial InGaAs.

2. The device of claim 1, wherein the substrate is made of GaAs, InP, or Si.

3. The device of claim 1, wherein the channel layer is made of GaAs, InGaAs, or InAs.

4. The device of claim 1, when the III-V semiconductor device is a high electron mobility transistor, the III-V semiconductor device further comprising:
a Schottky layer on the channel layer and under the gate; and
a cap layer on the Schottky layer exposed by the gate.

5. The device of claim 4, wherein the substrate is made of GaAs, InP, or Si.

6. The device of claim 4, wherein the channel layer is made of InGaAs or InAs.

7. A method of forming metal-semiconductor field effect transistor (MESFET), the method comprising:
Sequentially forming a channel layer and a hard mask layer on a substrate, wherein the channel layer is made of a III-V semiconductor;
Patterning the hard mask layer, the channel layer and the substrate to form two trenches in the channel layer and the substrate;
Forming a heavily-doped epitaxial semiconductor layer in the trenches and on the hard mask layer, wherein the epitaxial semiconductor layer is an epitaxial SiGe layer or an epitaxial InGaAs layer;
remove the hard mask layer and the epitaxial semiconductor layer on the hard mask layer to leave the epitaxial semiconductor layers in the trenches, is wherein the epitaxial semiconductor layers in the trenches are used as a source and a drain of the MESFET; and
Forming a gate on the channel layer and between the source and the drain.

8. The method of claim 7, wherein the substrate is made of GaAs, InP, or Si.

9. The method of claim 7, wherein the channel layer is made of GaAs, InGaAs, or InAs.

10. The method of claim 7, wherein the hard mask layer is made of a material comprises silicon oxide.

11. The method of claim 7, wherein the method of removing the hard mask layer comprises wet etching.

12. A method of forming high electron mobility transistor (HEMT), the method comprising:
sequentially forming a channel layer, a Schottky layer, a cap layer, and a hard mask layer on a substrate, wherein the channel layer is made of a III-V semiconductor layer;
pattering the hard mask layer, the cap layer, the Schottky layer, the channel layer, and the substrate to form two trenches in the cap layer, the Schottky layer, the channel layer, and the substrate;
forming a heavily-doped epitaxial semiconductor layer in the trenches and on the hard mask layer, wherein the epitaxial semiconductor layer is an epitaxial SiGe layer or an epitaxial InGaAs layer;
remove the hard mask layer and the epitaxial semiconductor layer on the hard mask layer to leave the epitaxial semiconductor layers in the trenches, wherein the epitaxial semiconductor layers in the trenches are used as a source and a drain of the HEMT; and
patterning the cap layer to form a gate opening in the cap layer; and
forming a gate in the gate opening and on the cap layer.

13. The method of claim 12, wherein the substrate is made of GaAs, InP, or Si.

14. The method of claim 12, wherein the channel layer is made of InGaAs or InAs.

15. The method of claim 12, wherein the Schottky layer is made of InAlAs.

16. The method of claim 12, wherein the cap layer is made of heavily doped InGaAs.

17. The method of claim 12, wherein the hard mask layer is made of a material comprising silicon oxide.

18. The method of claim 12, wherein the method of removing the hard mask layer comprises wet etching.

19. The method of claim 12, further comprising forming a passive layer on the exposed cap layer.

20. The method of claim 19, wherein the passive layer is made of a material comprising silicon nitride.
